(19) United States
(12) Patent Application Publication
(10) Pub. No.: US 2008/0057732 A1
(43) Pub. Date: Mar. 6, 2008

(54) METHOD FOR MANUFACTURING SILICON SUBSTRATE, METHOD FOR MANUFACTURING DROPLET DISCHARGING HEAD, AND METHOD FOR MANUFACTURING DROPLET DISCHARGING APPARATUS

(75) Inventor: Seiji YAMAZAKI, Shimosuwa-machi (JP)

Correspondence Address: WORKMAN NYDEGGER, 60 EAST SOUTH TEMPLE, 1000 EAGLE GATE TOWER, SALT LAKE CITY, UT, 84111, US

(73) Assignee: SEIKO EPSON CORPORATION, Tokyo (JP)

(21) Appl. No.: 11/833,821

(22) Filed: Aug. 3, 2007

(30) Foreign Application Priority Data
Aug. 29, 2006 (JP) 2006-232596

(51) Int. Cl. H01L 21/31

(52) U.S. Cl. 438/758

(57) ABSTRACT

A method for manufacturing a silicon substrate comprises: forming a silicon nitride film on a patterning area on a surface of a silicon base material; forming a silicon oxide film on an area excluding the patterning area on the surface of the silicon base material after forming the silicon nitride film; removing the silicon nitride film to expose the silicon base material of the patterning area; and etching the silicon base material of the patterning area.

### BACKGROUND

1. Technical Field

The present invention relates to a method for manufacturing a silicon substrate, a method for manufacturing a droplet discharging head, and a method for manufacturing a droplet discharging apparatus.

2. Related Art

A droplet discharging head driven by electrostatic force is required to be compact, low cost, densely fabricated, and have stable discharging characteristics. In order to satisfy these requirements, some droplet discharging heads have a four-layer structure composed of an electrode substrate, a cavity substrate, a reservoir substrate, and a nozzle substrate. Among these heads, there are a few cases in which a silicon base material is used as a reservoir substrate. Hence, process stability and yield improvement are required in manufacturing such a few droplet discharging heads in which the above reservoir substrate is used.

Some documents disclosed a droplet discharging head having a four-layer structure, provided with an electrode substrate, a cavity substrate, a reservoir substrate, and a nozzle substrate, and a method for manufacturing the head. For example, JP-A-2006-103167 (in pages 9 and 10, in FIGS. 8 and 9) indicated a method for manufacturing a reservoir substrate in which the reservoir substrate made of a silicon base material is manufactured by etching the silicon base material from the both sides.

The method for manufacturing a droplet discharging head disclosed in the above document, however, in which a reservoir (common droplet chamber) and a nozzle communicating hole are dry etched, has a problem in that a large etching area yields a wide variation in an etched depth and it's shape collapses easily. In addition, a nozzle communicating hole is formed through a silicon base material by etching the both sides of the material. This process easily forms a step inside the nozzle communicating hole due to misalignment. Further, the step sometimes yields a flight curve during a droplet discharging.

There are other examples of methods for manufacturing a droplet discharging head including a reservoir substrate made of a silicon base material. Among them, in a method in which a laser is not used for forming a nozzle communicating hole, a reservoir and the like is patterned after forming the nozzle communicating hole.

The above method needs to protect the nozzle communicating hole with resist to prevent a silicon oxide film formed inside the nozzle communicating hole from being etched. The process of covering the nozzle communicating hole with resist is, however, cumbersome and sometimes lowers a yield. Further, in a method in which a nozzle communicating hole is formed by using a laser, it takes a long time in processing.

### SUMMARY

An advantage of the invention is to provide a method for manufacturing a silicon substrate that can pattern a silicon base material without using resist, a method for manufacturing a droplet discharging head, and a method for manufacturing a droplet discharging apparatus, and especially, to provide a method for manufacturing a silicon substrate that can pattern a reservoir and an individual electrode terminal part without using resist after forming a nozzle communicating hole and prevent incomplete resist coverage of the nozzle communicating hole, a method for manufacturing a droplet discharging head having the substrate, and a method for manufacturing a droplet discharging apparatus having the head.

A method for manufacturing a silicon substrate according to a first aspect of the invention includes forming a silicon nitride (SiN) film on a patterning area on a surface of a silicon base material, forming a silicon oxide (SiO₂) film on an area excluding the patterning area on the surface of the silicon base material after forming the silicon nitride film, removing the silicon nitride film to expose the silicon base material of the patterning area, and etching the silicon base material of the patterning area.

The method enables the patterning area, on which the silicon nitride film is formed, to be patterned without using resist.

A method for manufacturing a silicon substrate according to a second aspect of the invention includes forming a first silicon oxide film on a surface of a silicon base material, forming a silicon nitride film on the first silicon oxide film corresponding to a patterning area on the surface of the silicon base material, forming a second silicon oxide film on the first silicon oxide film excluding the silicon nitride film after forming the silicon nitride film, removing the silicon nitride film, exposing the silicon base material of the patterning area, and etching the silicon base material of the patterning area.

The method enables the patterning area, on which the silicon nitride film is formed, to be patterned without using resist. In addition, the method can prevent the silicon base material from being roughed during a patterning when resist patterning is carried out on the silicon nitride film since the first silicon oxide film is formed under the silicon nitride film.

In this case, the silicon nitride film may be subjected to a resist patterning and etched so as to be formed in a shape of the patterning area.

The method can prevent the silicon base material from being roughed during the patterning since the resist patterning is carried out on the silicon nitride film with the first silicon oxide film formed under the silicon nitride film.

A method for manufacturing a droplet discharging head according to a third aspect of the invention includes a method for manufacturing a silicon substrate. The method for manufacturing a silicon substrate includes forming a silicon nitride film on a patterning area on a surface of a silicon base material, forming a silicon oxide film on an area excluding the patterning area on the surface of the silicon base material after forming the silicon nitride film, removing the silicon nitride film to expose the silicon base material of the patterning area, and etching the silicon base material of the patterning area.

The method can provide the droplet discharging head including the silicon substrate manufactured by the method in which the patterning area, on which the silicon nitride film is formed, is patterned without using resist.

A method for manufacturing a droplet discharging head according to a fourth aspect of the invention includes a method for manufacturing a silicon substrate. The method for manufacturing a silicon substrate includes forming a first silicon oxide film on a surface of a silicon base material, forming a silicon nitride film on the first silicon oxide film corresponding to a patterning area on the surface of the silicon base material, forming a second silicon oxide film on the first silicon oxide film excluding the silicon nitride film after forming the silicon nitride film, removing the silicon nitride film, exposing the silicon base material of the patterning area, and etching the silicon base material of the patterning area.

The method can provide the droplet discharging head including the silicon substrate manufactured by the method in which the patterning area, above which the silicon nitride film is formed, is patterned without using resist, and the surface of which can be prevented from being roughed during the patterning.

According to a fifth aspect of the invention, a method for manufacturing a droplet discharging head that is provided with a nozzle substrate having a nozzle hole, a cavity substrate having a nozzle communicating hole communicating with the nozzle hole and a discharge chamber discharging a droplet from the nozzle hole by pressure produced inside the discharge chamber, and a reservoir communicating with the discharge chamber includes a method for manufacturing a silicon substrate. The method for manufacturing a silicon substrate includes forming a silicon nitride film on a patterning area on a surface of a silicon base material, forming a silicon oxide film on an area excluding the patterning area on the surface of the silicon base material after forming the silicon nitride film, removing the silicon nitride film to expose the silicon base material of the patterning area, and etching the silicon base material of the patterning area. The reservoir substrate is made of the silicon base material.

The method can provide the droplet discharging head including the reservoir substrate that is made of the silicon base material and manufactured by the method in which the patterning area, on which the silicon nitride film is formed, is patterned without using resist.

According to a sixth aspect of the invention, a method for manufacturing a droplet discharging head that is provided with a nozzle substrate having a nozzle hole, a cavity substrate having a nozzle communicating hole communicating with the nozzle hole and a discharge chamber discharging a droplet from the nozzle hole by pressure produced inside the discharge chamber, and a reservoir communicating with the discharge chamber includes a method for manufacturing a silicon substrate. The method for manufacturing a silicon substrate includes forming a first silicon oxide film on a surface of a silicon base material, forming a silicon nitride film on the first silicon oxide film corresponding to a patterning area on the surface of the silicon base material, forming a second silicon oxide film on the first silicon oxide film excluding the silicon nitride film after forming the silicon nitride film, removing the silicon nitride film, exposing the silicon base material of the patterning area, and etching the silicon base material of the patterning area. The reservoir substrate is made of the silicon base material.

The method can provide the droplet discharging head including the reservoir substrate that is made of the silicon base material and is manufactured by the method in which the patterning area, on which the silicon nitride film is formed, is patterned without using resist and roughing the surface of the silicon base material.

In the fifth aspect of the invention, the patterning area may serve to form the reservoir and an individual electrode terminal part, and in the etching step, the silicon base material of the patterning area may be etched to form the reservoir and individual electrode terminal part.

The method can provide the droplet discharging head including the silicon substrate manufactured by the method in which the patterning area, on which the silicon nitride film is formed, is patterned without using resist and etched to form the reservoir and the individual electrode terminal part.

According to a seventh aspect of the invention, a method for manufacturing a droplet discharging head that is provided with a nozzle substrate having a nozzle hole, a cavity substrate having a nozzle communicating hole communicating with the nozzle hole and a discharge chamber discharging a droplet from the nozzle hole by pressure produced inside the discharge chamber, and a reservoir communicating with the discharge chamber includes a method for manufacturing a silicon substrate. The method for manufacturing a silicon substrate includes: forming a silicon nitride film on a patterning area on a first surface of the silicon base material, the patterning area serving to form the reservoir and an individual electrode terminal part; forming a silicon oxide film on an area excluding the patterning area on the first surface of the silicon base material after forming the silicon nitride film; etching the silicon base material from a second surface opposite to the first surface to form the nozzle communicating hole; removing the silicon nitride film to expose the silicon base material of the patterning area after forming the nozzle communicating hole; and etching the silicon base material of the patterning area to form the reservoir and individual electrode terminal part. The reservoir substrate is made of the silicon base material.

This method allows the patterning area serving to form the reservoir and the individual electrode terminal part on the reservoir base material to be patterned without using resist, and also the nozzle communicating hole to be prevented from incomplete resist coverage.

According to an eighth aspect of the invention, a method for manufacturing a droplet discharging head that is provided with a nozzle substrate having a nozzle hole, a cavity substrate having a nozzle communicating hole communicating with the nozzle hole and a discharge chamber discharging a droplet from the nozzle hole by pressure produced inside the discharge chamber, and a reservoir communicating with the discharge chamber includes a method for manufacturing a silicon substrate. The method for manufacturing a silicon substrate includes: forming a first silicon oxide film on a first surface of a silicon base material, forming a silicon nitride film on the first silicon oxide film corresponding to a patterning area on the first surface of the silicon base material, the patterning area serving to form the reservoir and an individual electrode terminal part; forming a second silicon oxide film on the first silicon oxide film excluding the silicon nitride film after forming the silicon nitride film; etching the silicon base material from a second surface opposite to the first surface to form the nozzle communicating hole; removing the silicon nitride film to expose the silicon base material of the patterning area after forming the nozzle communicating hole; and etching the silicon base material of the patterning area to form the reservoir and individual electrode terminal part. The reservoir substrate is made of the silicon base material.

This method allows the patterning area serving to form the reservoir and the individual electrode terminal part on the reservoir base material to be patterned without using resist, and also the nozzle communicating hole to be prevented from incomplete resist coverage. In addition, the first silicon oxide film formed under the silicon nitride film can prevent the surface of the reservoir base material from being roughed when the silicon nitride film is patterned. The first silicon oxide film also can prevent cooling gas from being leaked when the nozzle communicating hole is formed by dry etching.

A method for manufacturing a ninth aspect of the invention includes a method for manufacturing a droplet discharging apparatus including a method for manufacturing a droplet discharging head including a method for manufacturing a silicon substrate. The method for manufacturing a silicon substrate includes forming a silicon nitride film on a patterning area on a surface of a silicon base material, forming a silicon oxide film on an area excluding the patterning area on the surface of the silicon base material after forming the silicon nitride film, removing the silicon nitride film to expose the silicon base material of the patterning area, and etching the silicon base material of the patterning area.

The method can provide the droplet discharging apparatus including the droplet discharging head having the silicon substrate manufactured by the method in which the patterning area, on which the silicon nitride film is formed, is patterned without using resist.

A method for manufacturing a tenth aspect of the invention includes a method for manufacturing a droplet discharging apparatus including a method for manufacturing a droplet discharging head including a method for manufacturing a silicon substrate. The method for manufacturing a silicon substrate includes forming a first silicon oxide film on a surface of a silicon base material, forming a silicon nitride film on the first silicon oxide film corresponding to a patterning area on the surface of the silicon base material, forming a second silicon oxide film on the first silicon oxide film excluding the silicon nitride film after forming the silicon nitride film, removing the silicon nitride film, exposing the silicon base material of the patterning area, and etching the silicon base material of the patterning area.

The method can provide the droplet discharging apparatus including the droplet discharging head having the silicon substrate manufactured by the method in which the patterning area, on which the silicon nitride film is formed, is patterned and etched without using resist and roughing the surface of the silicon base material.

### BRIEF DESCRIPTION OF THE DRAWINGS

The invention will be described with reference to the accompanying drawings, wherein like number reference like elements.

FIG. 1 is an exploded perspective view of a droplet discharging head according to a first embodiment of the invention.

FIG. 2 is a vertical cross-sectional view of a state in which the droplet discharging head shown in FIG. 1 is assembled.

FIGS. 3A to 3D are sectional views illustrating manufacturing steps of a reservoir substrate of the first embodiment.

FIGS. 4A to 4D are sectional views illustrating manufacturing steps following the steps shown in FIGS. 3A to 3D.

FIGS. 5A to 5D are sectional views illustrating manufacturing steps following the steps shown in FIGS. 4A to 4D.

FIGS. 6A to 6D are sectional views illustrating manufacturing steps following the steps shown in FIGS. 5A to 5D.

FIGS. 7A and 7B are sectional views illustrating manufacturing steps following the steps shown in FIGS. 6A to 6D.

FIG. 8 is an explanatory diagram of a dry etching apparatus according to the first embodiment.

FIG. 9A is a sectional view illustrating a manufacturing step of the droplet discharging head of the first embodiment.

FIGS. 10A to 10D are sectional views illustrating manufacturing steps following the step shown in FIG. 9A.

FIGS. 11A and 11B are sectional views illustrating manufacturing steps following the steps shown in FIGS. 10A to 10D.

FIG. 12 is a sectional view illustrating manufacturing steps following the steps shown in FIGS. 11A and 11B.

FIG. 13 is a perspective view illustrating a droplet discharging apparatus using the droplet discharging head.

FIG. 14 is a perspective view illustrating major structural means of the droplet discharging apparatus.

### DESCRIPTION OF EXEMPLARY EMBODIMENTS

### First Embodiment

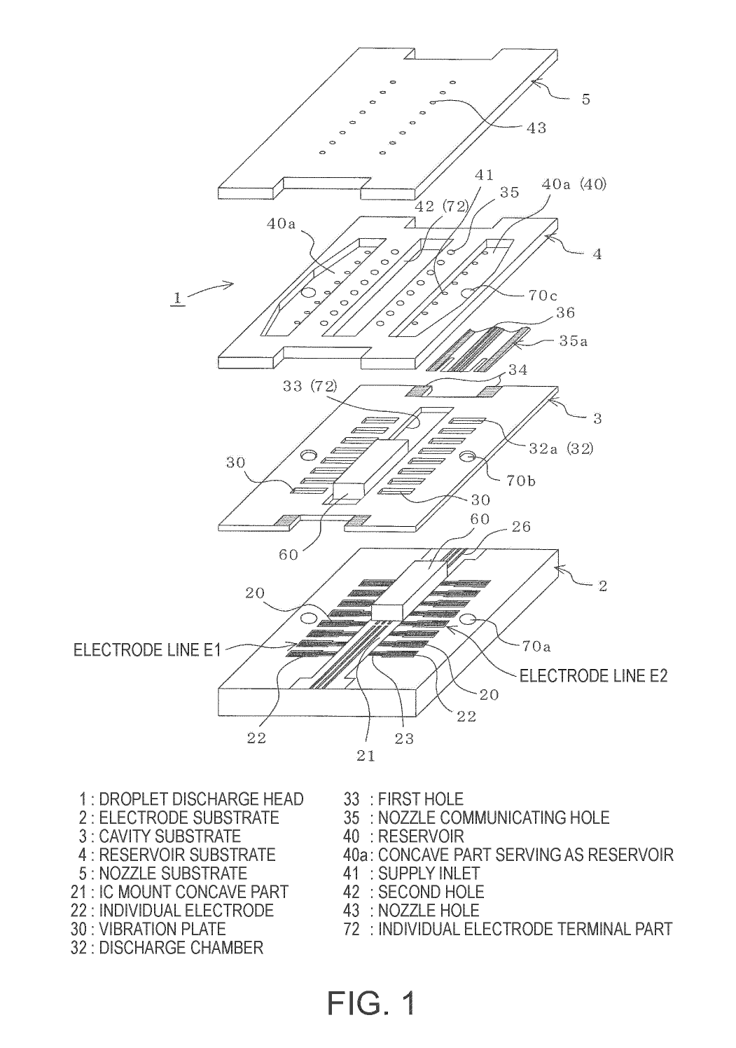

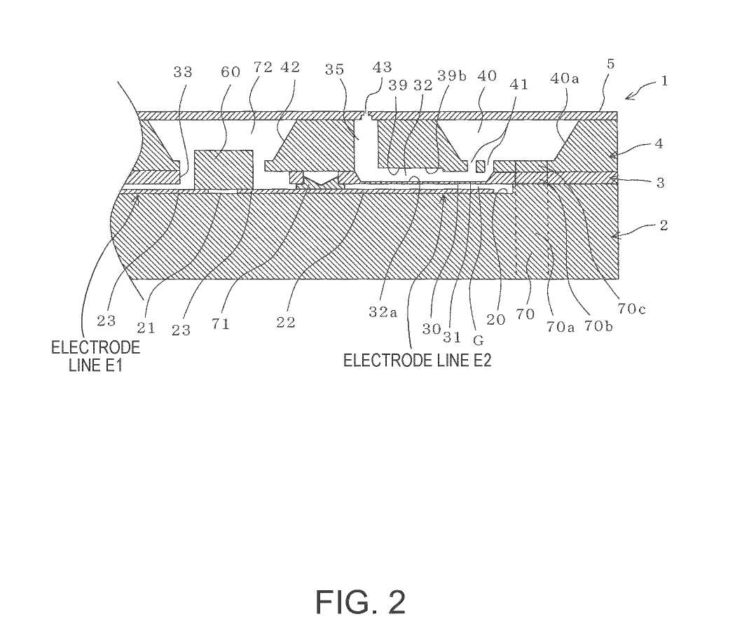

FIG. 1 is an exploded perspective view of a droplet discharging head according to a first embodiment of the invention. FIG. 2 is a vertical cross-sectional view of a state in which the droplet discharging head of the first embodiment is assembled. The droplet discharging head shown in FIGS. 1 and 2 is a face-eject type in which a droplet is discharged from a nozzle hole prepared in the surface of a nozzle substrate, and employs the electrostatic drive method driven by an electrostatic force.

Although it will be described that the nozzle substrate having the nozzle hole is located on an electrode substrate, the nozzle substrate is mostly located under the electrode substrate in actual use.

As shown in FIGS. 1 and 2, a droplet discharging head 1 is composed of an electrode substrate 2, a cavity substrate 3, a reservoir substrate 4 and a nozzle substrate 5. On one surface of the reservoir substrate 4, the nozzle substrate 5 is bonded while on the other surface of the reservoir substrate 4, the cavity substrate 3 is bonded. On one surface of the cavity substrate 3, the electrode substrate 2 is bonded. On the other surface opposite to the one surface, the reservoir substrate 4 is bonded. Inside the droplet discharging head 1, a driver IC 60 supplying a driving signal to an individual electrode (described later) is disposed.

The electrode substrate 2 has a thickness of about 1 mm and is made of heat resistance hard glass such as borosilicate glass having an approximate linear expansion coefficient to that of silicon, for example. In addition, a plurality of concave parts (electrode groove) 20, serving as an electrode chamber and having a depth of about 0.2 μm, for example, is formed by etching corresponding to respective discharge chambers (described later) formed in the cavity substrate 3. The concave parts 20 are formed in facing two lines, in each of which they are arranged with a constant interval. Inside each concave part 20, an individual electrode 22 and a terminal part 23 continuously formed from the individual electrode 22 are formed by sputtering indium tin oxide (ITO), for example. The individual electrodes 22 and the terminal parts 23 form electrode lines E1 and E2, in each of which, each long side of the individual electrodes 22 and the terminal parts 23 is in parallel each other. Each individual electrode 22 also arranged so as to face respective vibration plates (described later) prepared in the cavity substrate 3. Here, the pattern shape of the concave part 20 disposed in the electrode substrate 2 is made slightly larger than the shape of an electrode (the individual electrode 22 and the terminal part 23) since the electrode is prepared inside the concave part 20.

In the first embodiment, ITO, which is transparent and includes tin oxides doped as an impurity, is used for the material of the electrode prepared inside the concave part 20. ITO is deposited inside the concave part 20 as a film with a thickness of 0.1 μm by sputtering, for example. Therefore, a gap G formed between a vibration plate (described later) and the electrode depends on the depth of the concave part 20, the thickness of the electrode, and the vibration plate (TEOS film). The gap G greatly influences on discharge characteristics. The material for the electrode is not limited to ITO, but metal such as chromium may be used. The reason why ITO is used in the first embodiment is that the inside of the gap G is easily observed, discharge is easily checked due to its transparency and the like. The electrode substrate 2 also has a liquid supply hole 70a communicating with a reservoir (described later).

Between the electrode lines E1 and E2, an IC mount concave part (mount groove) 21 is formed orthogonally with respect to the long side direction of the individual electrode 22 so as to have a depth similar to that of the concave part 20 serving as the electrode chamber. In the IC mount concave part 21, three mount lead wires 26 are formed parallel reach other in the groove direction of the IC mount concave part 21 by sputtering ITO.

The driver IC 60 is mounted to the IC mount concave part 21 and connected to the terminal part 23 of the individual electrode 22 included in the electrode lines E1 and E2, allowing a driving signal to be supplied to the electrode lines E1 and E2 to control an actuator. While the droplet discharging head 1 has two driver ICs 60, the number of driver ICs 60 may be one or more than two.

The cavity substrate 3 is made of monocrystalline silicon having a (110) plane direction with a thickness of about 50 μm. In the cavity substrate 3, a concave part 32a is formed that serves as a discharge chamber 32 having a vibration plate 30 as the bottom wall thereof. The concave parts 32a are formed in two lines corresponding to individual electrodes 22 (in the electrode lines E1 and E2) of the electrode substrate 2. The cavity substrate 3 also has a first hole 33 passing through the cavity substrate 3 between two lines composed of the concave part 32a, and a common electrode 34 for applying voltage to the vibration plate 30. The common electrode 34 connects to an FPC 35a.

The vibration plate 30, prepared as the bottom wall of the concave part 32a serving as the discharge chamber, is a highly boron-doped layer. In order to form the vibration plate 30 having a desired thickness, boron-doped layer having the same thickness is formed. The thickness of the vibration plate 30 and the volume of the concave part 32a serving as the discharge chamber 32 are formed with high accuracy by using a called etching stop technique. The etching stop technique utilizes that an etching rate is enormously decreased in a highly doped region (about 5×10¹⁹ atoms·cm⁻³ or more) of boron serving as a dopant when silicon is subjected to an anisotropic wet etching with an alkaline aqueous solution.

The cavity substrate 3 has an insulation film 31 made of tetra-ethyl-ortho-silicate or tetra-ethoxy-silane (TEOS) with a thickness of 0.1 μm on the lower surface (the surface facing the electrode substrate 2). The insulation film 31 is formed by plasma chemical vapor deposition (CVD). The insulation film 31 prevents insulation breakdown and short circuits when the vibration plate 30 is driven. The cavity substrate 3 also has a liquid supply hole 70b, corresponding to the liquid supply hole 70a of the electrode substrate 2, passing through the cavity substrate 3. In addition, between the first hole 33 of the cavity substrate 3 and the concave parts 20 of the electrode substrate 2, a sealing member 71 is disposed to prevent the gap G from penetration of moisture or the like. The sealing member 71 can prevent the vibration plate 30 from adhering to the individual electrode 22.

The reservoir substrate 4 is made of monocrystalline silicon having a thickness of 180 μm, for example. The reservoir substrate 4 has two concave parts 40a, located at both sides thereof in the width direction so as to face each other. Each of the concave parts 40a serves as a reservoir 40 that supplies, for example, liquid like ink (hereinafter, referred to as ink) to the discharge chamber 32 of the cavity substrate 3. The concave part 40a has a supply inlet 41 on the bottom surface thereof to transfer ink from the reservoir 40 to each discharge chamber 32. The concave part 40a has a liquid supply hole 70c on the bottom surface thereof. The liquid supply hole 70c passes through the bottom surface of the concave part 40a. The liquid supply hole 70c formed in the reservoir substrate 4, the liquid supply hole 70b formed in the cavity substrate 3, and the liquid supply hole 70a formed in the electrode substrate 2 communicate each other to form a liquid supply hole 70 that supplies ink from an external source to the reservoir 40 when the reservoir substrate 4, the cavity substrate 3, and the electrode substrate 2 are bonded. In addition, between the reservoirs 40 facing each other in the reservoir substrate 4, a second hole 42 passing through the reservoir substrate 4 is formed.

The first hole 33 prepared in the cavity substrate 3 communicates with the second hole 42 prepared in the reservoir substrate 4 and further the resulting holes connect the IC mount concave part 21 prepared on the electrode substrate 2 to form an individual electrode terminal part 72. Inside the individual electrode terminal part 72, the driver IC 60 is housed while it is fixed to the IC mount concave part 21.

In addition, between the concave part 40a and the second hole 42 of the reservoir substrate 4, a nozzle communicating hole 35 communicating with the discharge chamber 32 is disposed to transfer ink from the discharge chamber 32 to a nozzle hole (described later) of the nozzle substrate 5.

The reservoir substrate 4 has a second concave part 39b on the surface thereof facing the concave part 32a of the cavity substrate 3 (on the bottom surface of the reservoir substrate 4). The second concave part 39b serves as a second discharge chamber 39 and form the discharge chamber 32 together with the concave part 32a of the cavity substrate 3 when the reservoir substrate 4 and the cavity substrate 3 are bonded.

The nozzle substrate 5 is made of a silicon base material having a thickness of about 50 μm, for example. The nozzle substrate 5 has a plurality of nozzle holes 43, each communicating with the respective nozzle communicating holes 35 of the reservoir substrate 4. Each of the nozzle holes 43 has a large-diameter part and a small-diameter part as two steps to improve straight flying property when a droplet is discharged.

In the droplet discharging head 1 structured as described above, the driver IC 60 fixed to the IC mount concave part 21 prepared in the electrode substrate 2 is housed in the individual electrode terminal part 72, which is closed by the nozzle substrate 5, the cavity substrate 3, the reservoir substrate 4 and the electrode substrate 2. That is, the individual electrode terminal part 72 is closed by the nozzle substrate 5 covering the upper surface of the individual electrode terminal part 72, the electrode substrate 2 covering the lower surface of the individual electrode terminal part 72, and the cavity substrate 3 and the reservoir substrate 4 both of which cover respective side surfaces of the individual electrode terminal part 72.

Next, the operation of the droplet discharging head 1 will be described with reference to FIG. 2. Ink is supplied from an external source to the reservoir 40 through the liquid supply hole 70, supplied from the reservoir 40 to the discharge chamber 32 through the supply inlet 41. The driver IC 60 received a driving signal (pulse voltage) from a controller (not shown) of the droplet discharge device 1 through an IC wiring line 36 of the FPC 35a and the lead wires 26 prepared on the electrode substrate 2.

For example, the driver IC 60 oscillates at 24 kHz and applies a pulse voltage of 30V between the electrodes to supply electric charges. When the individual electrode 22 is charged positive by supplying electric charges, the vibration plate 30 is charged negative and thereby is attracted to the individual electrode 22 to bend. This bending increases the volume of the discharge chamber 32. When electric charge supply to the individual electrode is stopped, the vibration plate 30 returns to the original shape. At the same time, the volume of the discharge chamber 32 also returns to the original one, resulting pressure discharging a droplet equivalent to the difference in the volume of the discharge chamber 32. The discharged droplet is landed on, for example, a recording paper as a recoding object to perform a recoding. Here, such method is a called drawing shot. There is also a called pushing shot discharging a droplet by using a spring or the like. Again, electric charges are supplied to the individual electrode 22 by applying a pulse voltage, so that the vibration plate 30 bends toward the individual electrode 22. As a result, ink is resupplied from the reservoir 40 into the discharge chamber 32 through the supply inlet 41.

In the droplet discharging head 1, ink is supplied to the reservoir 40 through a droplet supply tube (not shown) connected to the liquid supply hole 70, for example.

Also, in the first embodiment, the FPC 35a is connected to the driver IC 60 so that the longitudinal direction of the FPC 35a is in parallel with the short side direction of the individual electrode 22 included in the electrode lines. This structure allows the droplet discharging head 1 including the electrode lines E1 and E2, and the FPC 35a to be compactly connected.

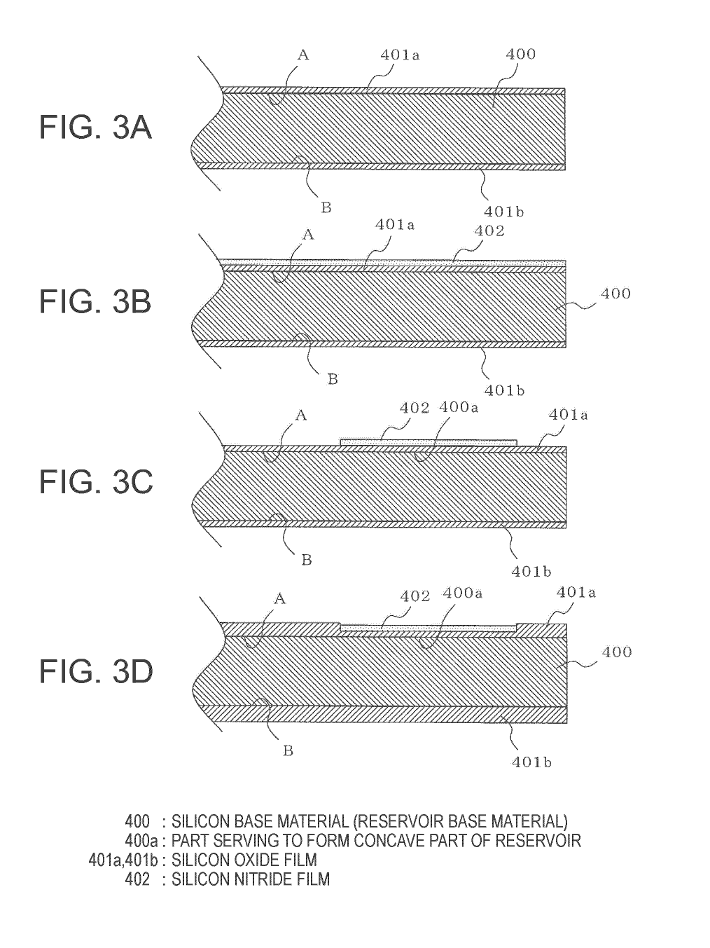

Next, manufacturing steps of the droplet discharging head 1 will be described with reference to FIGS. 3A to 12. While the component of droplet discharging head 1 is simultaneously formed in a plurality of numbers from a silicon wafer in practice, only a part of them is shown in FIGS. 3A to 12.

First, the manufacturing steps of a reservoir base plate 4 made of a silicon base material will be described with reference to FIGS. 3A to 8. (a) The both surfaces of a silicon base material 400 (reservoir base material) having a (100) plane direction are mirror polished to achieve a base material having a thickness of 180 μm. As for the both surfaces, hereinafter, on surface to which the nozzle substrate 5 is connected is referred to as a surface A while the other surface to which the cavity substrate 3 is connected is referred to as a surface B. Then, as shown in FIG. 3A, silicon oxide (SiO₂) films 401a and 401b having a thickness of about 0.1 μm are formed on both surfaces A and B of the silicon base material 400 respectively by oxidizing it at 1000° C. for three hours in an oxygen atmosphere.

(b) As shown in FIG. 3B, a silicon nitride (SiN) film 402 is formed on the surface A of the silicon base material 400 by plasma CVD. The film is formed with a thickness of 0.1 μm by the following conditions: the processing temperature is 500° C. or less, the pressure is 1.3 kPa or less (10 Torr or less), and the gas flow ratio (NH₃/SiH₄) is 15 or more.

In the above steps, the silicon nitride film 402 is formed in step (b) after step (a). Here, in step (a), the silicon oxide films 401a and 401b are formed on the surfaces A and B of the silicon base material 400, respectively, while in step (b), the silicon nitride film 402 is formed on the surface A of the silicon base material 400 by plasma CVD. However, the silicon nitride film 402 can be formed on the surface A of the silicon base material 400 by plasma CVD after mirror polishing the surfaces A and B of the silicon base material 400 without forming the silicon oxide films 401a and 401b on the surfaces A and B, respectively.

(c) A resist is coated on the silicon nitride film formed on the surface A. Then, as shown in FIG. 3C, resist patterning is carried out for a part 400a in which the concave part 40a of the reservoir 40 will be formed and for a part (not shown) in which the second hole 42 included in the individual electrode terminal part 72 will be formed. Next, the resist is removed by etching the silicon nitride film 402 with a reactive ion etching (RIE) apparatus under the following conditions: the pressure is 26.6 Pa (0.2 Torr), the RF power is 200 W, and the gas flow rate is 30 cc/minute.

In the process, in which the silicon nitride film 402 is formed after forming the silicon oxide films 401a and 401b on the silicon base material 400 and then resist patterning is carried out on the silicon nitride film 402, the surface of the silicon base material 400 is prevented from being etched by etching gas since the silicon oxide film 401a, the layer under the silicon nitride film 402, functions as a mask.

(d) Then, as shown in FIG. 3D, silicon oxide films 401a and 401b having a thickness of about 1.2 μm are grown and formed on both surfaces A and B of the silicon base material 400 respectively by oxidizing it at 1075° C. for four hours in an oxygen and moisture atmosphere. The silicon oxide films 401a and 401b are not grown on a part on which the silicon nitride film 402 has been formed.

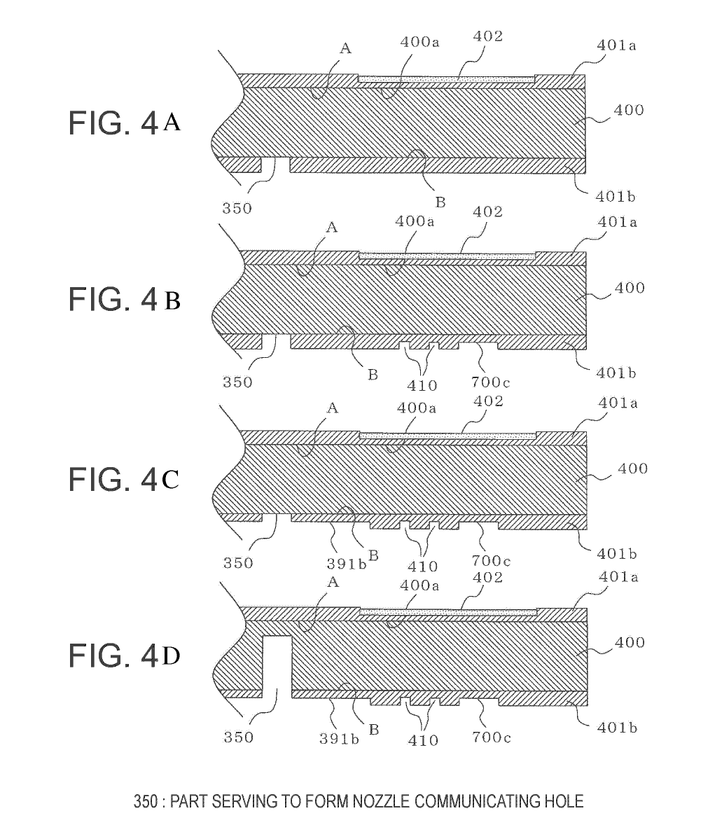

(e) A resist is coated above the surfaces A and B of the silicon base material 400. Then, resist patterning is carried out for a part 350, in which the nozzle communicating hole 35 will be formed, on the surface B. Next, the silicon oxide film 401b is patterned by etching with a fluoric acid aqueous solution as shown in FIG. 4E. Then, the resist is removed.

(f) A resist is coated above the surfaces A and B of the silicon base material 400. Then, resist patterning is carried out for a part 410 in which the supply outlet 41 through which the reservoir 40 communicates with the discharge chamber 32 will be formed, a part 700 c in which the liquid supply hole 70c to supply ink from the cavity substrate 3 will be formed, and a part (not shown) in which the hole 42 included in the individual electrode terminal part 72 will be formed, above the surface B in which the part 350 serving to form the nozzle communicating hole 35 is formed. Next, the silicon oxide film 401b is patterned by etching with a fluoric acid aqueous solution by about 0.8 μm deep so as to leave the silicon oxide film having a thickness of about 0.4 μm, as shown in FIG. 4F. Then, the resist is removed.

(g) A resist is coated above the surfaces A and B of the silicon base material 400. Then, resist patterning is carried out for a part 391b, in which a second concave part 390b will be formed, above the surface B in which the part 350 serving to form the nozzle communicating hole 35 is formed. Next, the silicon oxide film 401b is patterned by etching with a fluoric acid aqueous solution by about 0.5 μm deep so as to leave the silicon oxide film 401b having a thickness of about 0.7 μm, as shown in FIG. 4C. Then, the resist is removed.

(h) The part 350 serving to form the nozzle communicating hole 35 is etched by about 150 μm deep as shown in FIG. 4D by using an ICP dry etching apparatus (described later). The etching is carried out by the following conditions. The etching process is as follows: the SF₆ flow rate is 400 cm³/minute (400 sccm), the etching time is 3.5 seconds, the chamber pressure is 8 Pa, the coil power is 2200 W, the platen power is 55 W, and the platen temperature is 20° C. The deposition process is as follows: C₄F₈ flow rate is 200 cm³/minute (200 sccm), the etching time is 2.5 seconds, the chamber pressure is 2.7 Pa, the coil power is 1800 W, and the platen temperature is 20° C. The etching process and deposition process equals one cycle. About 380 cycles are carried out.

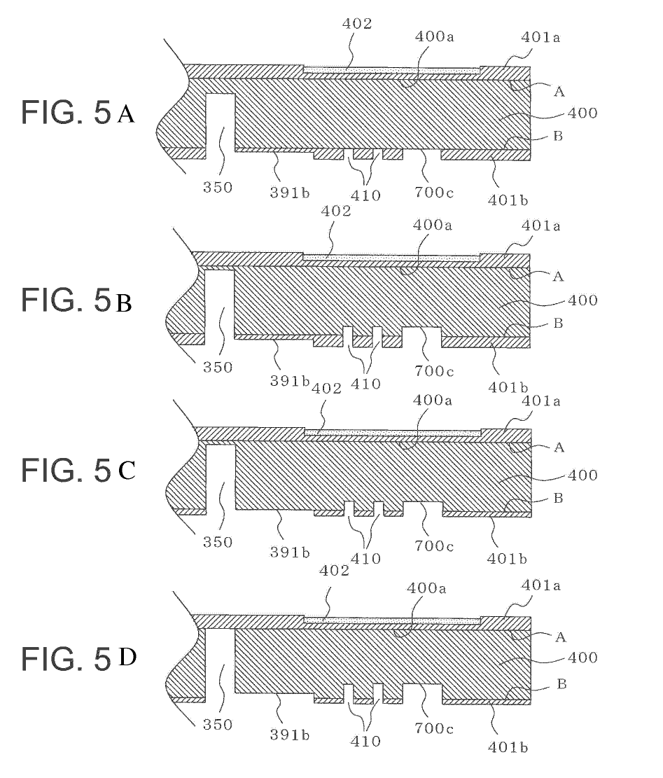

(i) A resist is coated above the surface A. The silicon oxide film 401b that remains at the part 410, in which the supply inlet 41 will be formed, and the like is etched as shown in FIG. 5I by soaking the silicon base material 400 in a fluoric acid aqueous solution. Then, the resist is removed.

(j) The part 410 serving to form the supply inlet 41 is etched by about 20 μm deep (the part 350 serving to form the nozzle communicating hole 35 is etched by about 170 μm deep) as shown in FIG. 5B by using an ICP dry etching apparatus. The etching is carried out by the following conditions. The etching process is as follows: the SF₆ flow rate is 400 cm³/minute (400 sccm), the etching time is 3.5 seconds, the chamber pressure is 8 Pa, the coil power is 2200 W, the platen power is 55 W, and the platen temperature is 20° C. The deposition process is as follows: C₄F₈ flow rate is 200 cm³/minute (200 sccm), the etching time is 2.5 seconds, the chamber pressure is 2.7 Pa, the coil power is 1800 W, and the platen temperature is 20° C. The etching process and deposition process equals one cycle. About 50 cycles are carried out.

(k) A resist is coated above the surface A. The silicon oxide film 401b that remains at the part 391b, in which the second concave part 390b will be formed, and the like is etched as shown in FIG. 5C by soaking the silicon base material 400 in a fluoric acid aqueous solution. Then, the resist is removed.

(l) The part 391b, in which the second concave part 390b will be formed, is etched by about 10 μm deep (the part 350 corresponding to the nozzle communicating hole 35 is etched by about 180 μm deep and the part 410 serving to form the supply inlet 41 and the like are etched by about 30 μm deep) as shown in FIG. 5D by using an ICP dry etching apparatus. The etching is carried out by the following conditions. The etching process is as follows: the SF₆ flow rate is 400 cm³/minute (400 sccm), the etching time is 3.5 seconds, the chamber pressure is 8 Pa, the coil power is 2200 W, the platen power is 55 W, and the platen temperature is 20° C. The deposition process is as follows: C₄F₈ flow rate is 200 cm³/minute (200 sccm), the etching time is 2.5 seconds, the chamber pressure is 2.7 Pa, the coil power is 1800 W, and the platen temperature is 20° C. The etching process and deposition process equals one cycle. About 25 cycles are carried out. In the step, the part 350 serving to form the nozzle communicating hole 35 passes through the silicon substrate 400, but the silicon oxide film 401a remains at the bottom of the part 350 (on the same plane of the surface A). The silicon oxide film 401a can prevent cooling gas of the etching apparatus from being leaked.

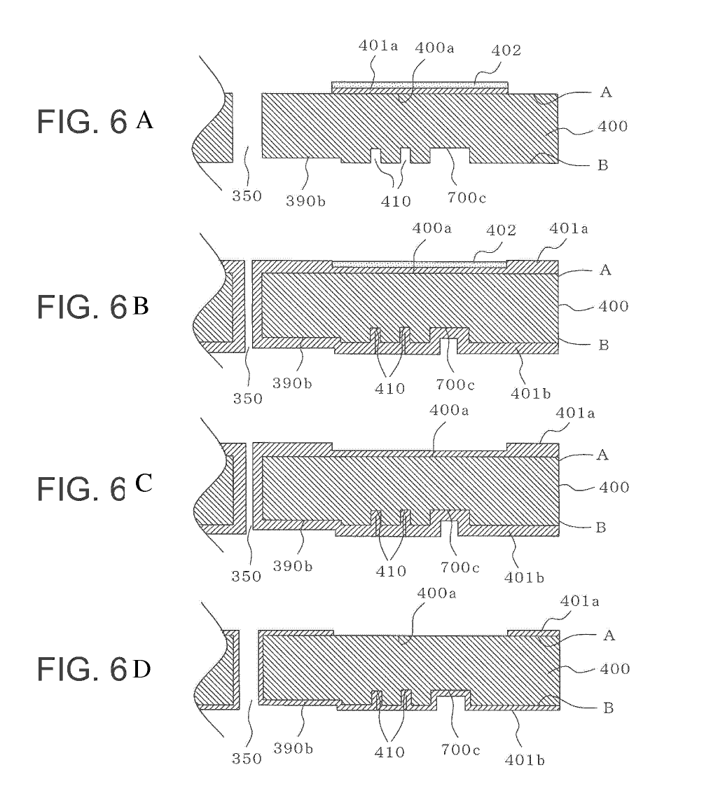

(m) The silicon oxide films 401a and 401b are etched as shown in FIG. 6A by soaking the silicon base material 400 in a fluoric acid aqueous solution.

(n) As shown in FIG. 6B, silicon oxide films 401a and 401b having a thickness of about 1.7 μm are formed on both surfaces of the silicon base material 400 respectively by oxidizing it at 1075° C. for eight hours in an oxygen and moisture atmosphere. In this step, in the same manner of the step shown in FIG. 3D, the silicon oxide film 401a is not grown on a part on which the silicon nitride film 402 has been formed.

(o) Silicon oxide film slightly formed on the surface of the silicon nitride film 402 is removed by soaking the silicon base material 400 in a fluoric acid aqueous solution (not shown). Then, the silicon base material 400 is soaked in a heated phosphoric acid aqueous solution (180° C.) to remove the silicon nitride film 402 that remains on the part 400a in which the reservoir 40 will be formed and a part (not shown) in which the second hole 42 included in the individual electrode terminal part 72 will be formed, as shown in FIG. 6C.

(p) The silicon base material 400 is soaked in a fluoric acid aqueous solution to etch the silicon oxide film 401a that covers the part 400a in which the concave part 40a of the reservoir 40 will be formed and a part (not shown) in which the second hole 42 included in the individual electrode terminal part 72 will be formed so that the surface of the silicon base material 400 is exposed as shown in FIG. 6D.

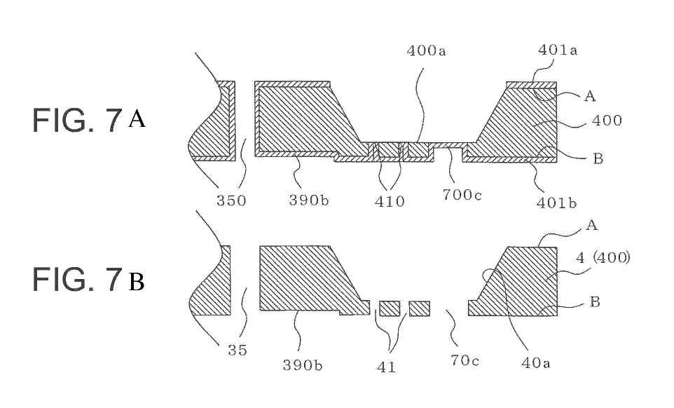

(q) The silicon base material 400 is soaked in a potassium hydrate aqueous solution of a concentration of 25 wt % to etch the part 440a in which the concave part 40a of the reservoir 40 will be formed and the part (not shown) in which the second hole 42 included in the individual electrode terminal part 72 as shown in FIG. 7Q. The part 440a in which the concave part 40a of the reservoir 40 will be formed and the part in which the second hole 42 included in the individual electrode terminal part 72 are etched until the silicon oxide film 401b formed on a surface adjacent to the surface B is disposed as shown in FIG. 7Q.

(r) The silicon oxide films 401a and 401b are removed as shown in FIG. 7B by soaking the silicon base material 400 in a fluoric acid aqueous solution.

Through the above manufacturing steps from (a) to (r), the reservoir substrate 4 is achieved as shown in FIG. 7B.

In the manufacturing steps, the concave part 40a of the reservoir 40 is formed by etching the part 440a serving to form the concave part 40a of the reservoir 40 while the second hole 42 included in the individual electrode terminal part 72 is formed by etching the part serving to form the second hole 42 included in the individual electrode terminal part 72. The etching process is carried out after the nozzle communicating hole 35 is passed through (FIG. 5D). The penetration of the nozzle communicating hole 35 is carried out by using an ICP dry etching apparatus from a side adjacent to the part 350 serving to form the nozzle communicating hole 35.

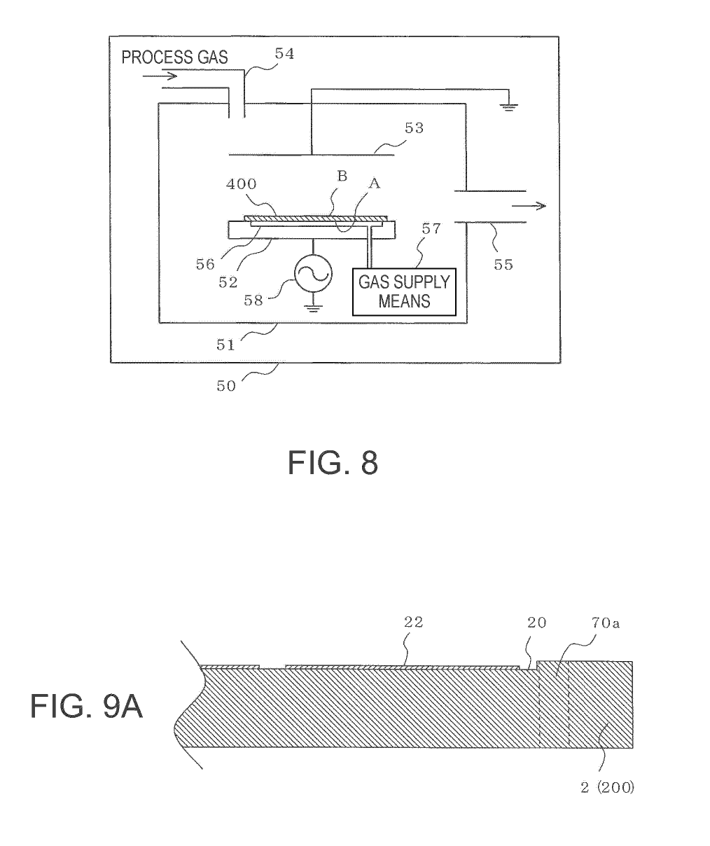

FIG. 8 is a schematic view illustrating a dry etching apparatus. A dry etching apparatus 50 has a cathode 52 in a chamber 51 as shown in FIG. 8. The cathode 52 serves as a support table to place and fix the silicon base material 400 with a chucking mechanism, and also functions as an electrode upon receiving power from a power supply means 58. Facing to the cathode 52 an anode 53 is disposed as a counter electrode. Process gas to carry out etching is supplied from a supply tube 54 to the inside of the chamber 51 and exhausted by a pump (not shown) through an exhausted tube 55 to maintain the inside of the chamber 51 at a predetermined pressure.

The cathode 52 has a concave part 56, which is filled with base material cooling gas such as helium to prevent the silicon base material 400 from being over heated. Overheating the silicon base material 400 may affect an etching speed and the oxidization process of the silicon base material 400. If a resist is used as a mask, the resist may get burned. Thus, the temperature of the silicon base material 400 is maintained with base material cooling gas. In this regard, the silicon base material 400 functions as a called lid to prevent base material cooling gas from leaking in the inside of the chamber 51.

For dry etching the silicon base material 400, the silicon base material 400 is placed inside the chamber 51 of the dry etching apparatus 50 as shown in FIG. 8. The silicon base material 400 is placed so that the surface A thereof faces the cathode 52. Here, the surface A is connected to the nozzle substrate 5. While the silicon base material 400 is kept in this state, the part 350 serving to form the nozzle communicating hole 35 and the like are dry etched to form a hole having a predetermined depth from a side adjacent to the surface B by utilizing inductively coupled plasma (ICP) or the like. Here, dry etching and process gas are not limited to any kind, as long as they can etch the silicon base material 400. For example, sulfur hexafluoride (SF₆) can be used.

Next, steps to manufacture the droplet discharging head 1 by using the reservoir substrate 4 manufactured as described above will be described. FIGS. 9A to 12 are schematic views illustrating the manufacturing step of the droplet discharging head 1.

While the component of droplet discharging head 1 is simultaneously formed in a plurality of numbers from a silicon wafer in practice, only a part of them is shown in FIG. 9A through FIG. 12.

(a) As shown in FIG. 9A, the concave part 20 serving as an electrode groove having a depth of 0.2 μm is formed to a glass base material 200 of having a thickness of about 1 mm by aligning with the shape pattern of the electrode. After the concave part 20 is formed, the electrode 22 is formed with a thickness of 0.1 μm by sputtering. Then, the liquid supply hole 70a is formed by sandblasting or cutting work.

(b) A cavity base material 300 is prepared. The cavity base material 300 is formed to have a thickness of 220 μm by mirror polishing one surface of a silicon base material having a (110) plane direction and low oxygen concentration. To the mirror polished surface of the cavity base material 300, a highly boron doped layer (not shown) is formed with a thickness equal to that of the vibration plate. In addition, on the surface of the boron doped layer, a TEOS insulation film (not shown) is formed with a thickness of 0.1 μm.

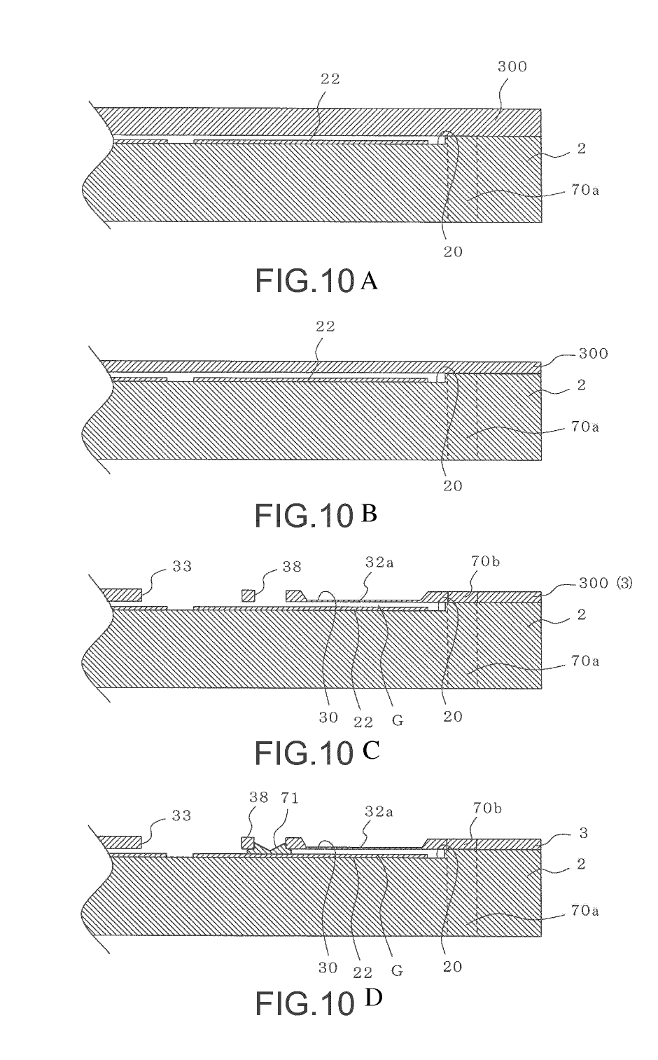

Next, the cavity base material 300 and the electrode substrate 2 on which a pattern has been formed are heated at 360° C. Then, the cavity base material 300 and the electrode substrate 2 are anodic bonded by applying a voltage of 800 V after the electrode substrate 2 is connected to a negative pole while the cavity base material 300 is connected to a positive pole, as shown in FIG. 10A.

(c) After the anodic bonding, the surface of the cavity base material 300 is grinded to a thickness of about 60 μm. Then, the cavity base material 300 is etched by about 10 μm with a potassium hydrate aqueous solution of a concentration of 32 wt % to remove a work-affected layer. As a result, the cavity base material having a thickness of about 50 μm is achieved as shown in FIG. 10B.

(d) The cavity base material 300, which has been subjected to the anodic bonding, is etched by using a potassium hydrate aqueous solution to form the concave part 32a serving to form the discharge chamber 32. In this silicon etching process, etching is stopped at the boron doped layer due to decreasing of the etching rate. This process suppresses the surface of the vibration plate 30 from being roughed to increase the thickness accuracy, allowing the discharge performance of the droplet head 1 to be stabilized. In this regard, silicon thin film remains in the through holes such as the first hole 33 included in the individual electrode terminal part 72. In order to remove the film, plasma is applied only to the through hole for RIE dry etching after fixing a silicon mask on the surface of the cavity base material 300. As a result, the film is removed to form an opening whereby the cavity substrate 3 is achieved as shown in FIG. 10C.

(e) The bonded base materials shown in FIG. 10C are dried to remove moisture inside the gap G. As shown in FIG. 10D, the gap G is sealed with a sealing member 71 of an epoxy resin by pouring the epoxy resin into a though hole 38 for sealing the gap G. As a result, the gap G is sealed up.

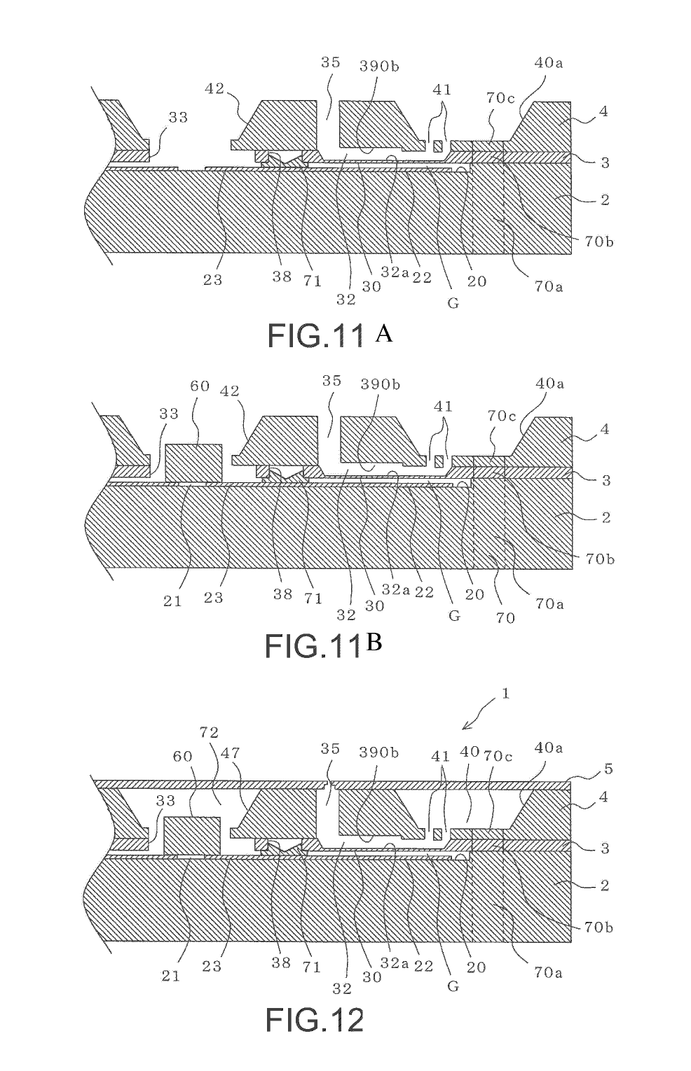

(f) The reservoir substrate 4, which has been manufactured in steps shown in FIGS. 3A to 7B, is bonded to the cavity substrate 3 with an epoxy resin adhesive as shown in FIG. 11A.

(g) As shown in FIG. 11B, the driver IC 60 is mounted to the terminal part 23 of the electrode substrate 2.

(h) As shown in FIG. 12, the nozzle substrate 5 is bonded to the reservoir substrate 4 with an epoxy resin adhesive. Then, an individual head is achieved after a cutting by dicing.

The droplet discharging head 1 according to the invention can be easily handled since parts such as the concave part 32a serving to form the discharge chamber 32 are formed in the cavity base material 300 after the cavity base material 300 and the electrode substrate 2 are bonded. The easy handling can reduce the breakage of the base material and achieve a larger size base material. The larger size base material allows the larger number of droplet discharging heads 1 to be manufactured from a single base material, enabling the productivity to be increased. In addition, stacking the reservoir substrate 4 thicker than the cavity substrate 3 on the cavity substrate 3 reduces the flow path resistance of the reservoir 40, allowing discharge capacity to be improved and a head to be downsized.

The reservoir substrate 4 of the droplet discharging head 1 is processed as follows: the silicon nitride film 402 is formed on the patterning areas for the concave part 40a of the reservoir 40 and the second hole 42 of the individual electrode terminal part 72; the silicon oxide film 401a is formed as a mask in silicon etching; the silicon nitride film 402 is removed; and the concave part 40a of the reservoir 40 and the second hole 42 of the individual electrode terminal part 72 are patterned. Using such manufacturing method allows the concave part 40a of the reservoir 40 and the second hole 42 of the individual electrode terminal part 72 to be patterned without resist after forming the nozzle communicating hole 35. As a result, incomplete resist coverage of the nozzle communicating hole 35 can be prevented.

Also, in manufacturing the reservoir substrate 4 of the droplet discharging head 1, the silicon oxide film 401a can be formed thin as an underlayer prior to forming the silicon nitride film 402. The underlayer can prevent the surface of the reservoir base material 400 from being roughed in patterning the silicon nitride film 402, and also prevent cooling gas from being leaked when the nozzle communicating hole 35 is passed through during the dry etching.

### Second Embodiment

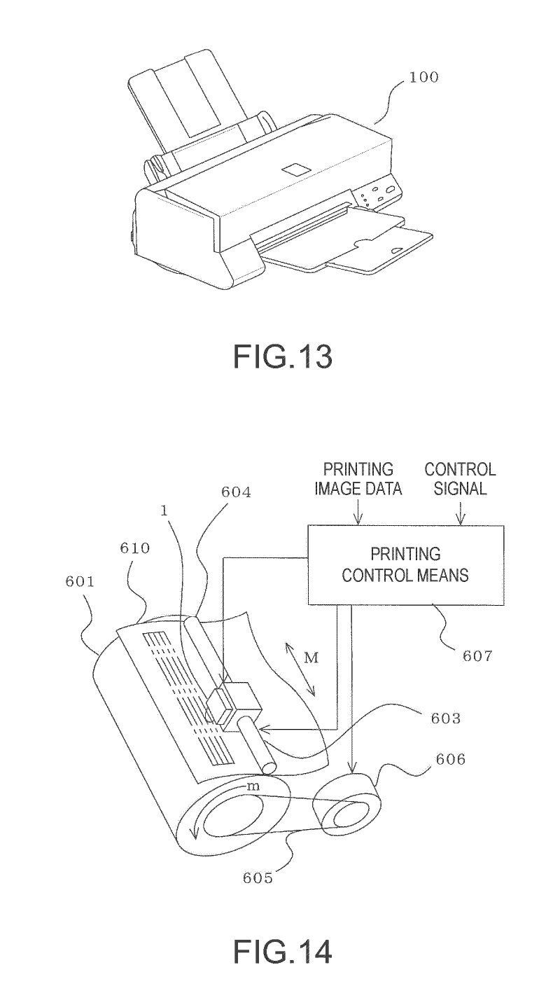

FIG. 13 is a perspective view illustrating a droplet discharging apparatus using the droplet discharging head 1 manufactured in the first embodiment. FIG. 14 is a perspective view illustrating major structural means of the droplet discharging apparatus shown in FIG. 13. A droplet discharging apparatus 100 in FIG. 13 performs printing by a droplet discharge method (inkjet method) and belongs to a called serial type.

As shown in FIG. 14, the droplet discharging apparatus 100 mainly includes a drum 601 and the droplet discharging head 1 as major structural means. The drum 601 supports a printing paper 610. The droplet discharging head 1 discharges ink to the printing paper 610 for performing a record. In addition, ink supply means (not shown) is provided for supplying ink to the droplet discharging head 1. The printing paper 610 is pressed and held to the drum 601 by a paper pressing-holding roller 603 disposed in parallel with the axial direction of the drum 601. In parallel with the axial direction of the drum 601, a lead screw 604 is disposed to hold the droplet discharging head 1. By rotating the lead screw 604, the droplet discharging head 1 moves in the axial direction of the drum 601.

On the other hand, the drum 601 is rotary driven by a motor 606 with a belt 605 and the like. In addition, printing control means 607 drives the lead screw 604 and the motor 606 based on printing image data and a control signal, and an oscillation circuit (not shown) to vibrate the vibration plate 30. As a result, a printing is carried out on the printing paper 610 under the control of the printing control means 607.

While liquid is discharged to the printing paper 610 as ink in this case, liquid discharged from the droplet discharging head 1 is not limited to ink. A variety of liquid may be discharged from a droplet discharging head provided in respective apparatuses used in the following exemplary cases. In an application where liquid is discharged to a substrate serving as a color filter, liquid containing a pigment may be used. In another application where liquid is discharged to a substrate serving as a display panel (such as OLED) using an electroluminescent element such as an organic compound, liquid containing a compound serving as an light-emitting element may be used. In another application where liquid is discharged on a substrate for forming electrical wire lines, liquid containing conductive metal may be used. When liquid is discharged to a substrate serving as a biomolecule micro array by using the droplet discharging head as a dispenser, liquid may be discharged that contains a probe such as deoxyribo nucleic acids (DNA), other nucleic acids such as ribo nucleic acids and peptide nucleic acids, and other proteins. The apparatus also can be used to discharge a dye for clothes or the like.

What is claimed is:

1. A method for manufacturing a silicon substrate, comprising:
forming a silicon nitride film on a patterning area on a surface of a silicon base material;
forming a silicon oxide film on an area excluding the patterning area on the surface of the silicon base material after forming the silicon nitride film;
removing the silicon nitride film to expose the silicon base material of the patterning area; and
etching the silicon base material of the patterning area.

2. A method for manufacturing a silicon substrate, comprising:
forming a first silicon oxide film on a surface of a silicon base material;
forming a silicon nitride film on the first silicon oxide film corresponding to a patterning area on the surface of the silicon base material;
forming a second silicon oxide film on the first silicon oxide film excluding the silicon nitride film after forming the silicon nitride film;
removing the silicon nitride film; exposing the silicon base material of the patterning area; and
etching the silicon base material of the patterning area.

3. The method for manufacturing a silicon substrate according to claim 2, wherein the silicon nitride film is subjected to a resist patterning and etched so as to be formed in a shape of the patterning area.

4. A method for manufacturing a droplet discharging head manufactured by using a method for manufacturing a silicon substrate, the method comprising:
forming a silicon nitride film on a patterning area on a surface of a silicon base material;
forming a silicon oxide film on an area excluding the patterning area on the surface of the silicon base material after forming the silicon nitride film;
removing the silicon nitride film to expose the silicon base material of the patterning area; and
etching the silicon base material of the patterning area.

5. A method for manufacturing a droplet discharging head manufactured by using a method for manufacturing a silicon substrate, the method comprising:
forming a silicon oxide film on a surface of a silicon base material;
forming a silicon nitride film on the first silicon oxide film corresponding to a patterning area on the surface of the silicon base material; forming a second silicon oxide film on the first silicon oxide film excluding the silicon nitride film after forming the silicon nitride film;
removing the silicon nitride film; exposing the silicon base material of the patterning area; and
etching the silicon base material of the patterning area.

6. A method for manufacturing a droplet discharging head that includes a nozzle substrate having a nozzle hole, a cavity substrate provided with a nozzle communicating hole communicating with the nozzle hole and a discharge chamber discharging a droplet from the nozzle hole, and a reservoir communicating with the discharge chamber, the method comprising:
a method for manufacturing a silicon substrate including:
forming a silicon nitride film on a patterning area on a surface of a silicon base material;
forming a silicon oxide film on an area excluding the patterning area on the surface of the silicon base material after forming the silicon nitride film;
removing the silicon nitride film to expose the silicon base material of the patterning area; and
etching the silicon base material of the patterning area, wherein the reservoir substrate is made of the silicon base material.

7. A method for manufacturing a droplet discharging head that includes a nozzle substrate having a nozzle hole, a cavity substrate provided with a nozzle communicating hole communicating with the nozzle hole and a discharge chamber discharging a droplet from the nozzle hole, and a reservoir communicating with the discharge chamber, the method comprising:
a method for manufacturing a silicon substrate including:
forming a silicon oxide film on a surface of a silicon base material serving as the reservoir substrate;
forming a silicon nitride film on the first silicon oxide film corresponding to a patterning area on the surface of the silicon base material;
forming a second silicon oxide film on the first silicon oxide film excluding the silicon nitride film after forming the silicon nitride film;
removing the silicon nitride film;
exposing the silicon base material of the patterning area; and
etching the silicon base material of the patterning area, wherein the reservoir substrate is made of the silicon base material.

8. The method for manufacturing a droplet discharging head according to claim 6, wherein the patterning area serves to form the reservoir and an individual electrode terminal part, and in the etching step, the silicon base material of the patterning area is etched to form the reservoir and individual electrode terminal part.

9. A method for manufacturing a droplet discharging head that includes a nozzle substrate having a nozzle hole, a cavity substrate having a nozzle communicating hole communicating with the nozzle hole and a discharge chamber discharging a droplet from the nozzle hole by pressure produced inside the discharge chamber, and a reservoir communicating with the discharge chamber, the method comprising:
forming a silicon nitride film on a patterning area on a first surface of the silicon base material, the patterning area serving to form the reservoir and an individual electrode terminal part;
forming a silicon oxide film on an area excluding the patterning area on the first surface of the silicon base material after forming the silicon nitride film;
etching the silicon base material from a second surface opposite to the first surface to form the nozzle communicating hole;
removing the silicon nitride film to expose the silicon base material of the patterning area after forming the nozzle communicating hole; and
etching the silicon base material of the patterning area to form the reservoir and individual electrode terminal part, wherein the reservoir substrate is made of the silicon base material.

10. A method for manufacturing a droplet discharging head that includes a nozzle substrate having a nozzle hole, a cavity substrate having a nozzle communicating hole communicating with the nozzle hole and a discharge chamber discharging a droplet from the nozzle hole by pressure produced inside the discharge chamber, and a reservoir communicating with the discharge chamber, the method comprising:
forming a first silicon oxide film on a first surface of a silicon base material;
forming a silicon nitride film on the first silicon oxide film corresponding to a patterning area on the first surface of the silicon base material, the patterning area serving to form the reservoir and an individual electrode terminal part;
forming a second silicon oxide film on the first silicon oxide film excluding the silicon nitride film after forming the silicon nitride film;
etching the silicon base material from a second surface opposite to the first surface to form the nozzle communicating hole;
removing the silicon nitride film to expose the silicon base material of the patterning area after forming the nozzle communicating hole; and
etching the silicon base material of the patterning area to form the reservoir and individual electrode terminal part, wherein the reservoir substrate is made of the silicon base material.

11. A method for manufacturing a droplet discharging apparatus, comprising: a method for manufacturing a droplet discharging head including a method for manufacturing a silicon substrate including:
forming a silicon nitride film on a patterning area on a surface of a silicon base material;
forming a silicon oxide film on an area excluding the patterning area on the surface of the silicon base material after forming the silicon nitride film;
removing the silicon nitride film to expose the silicon base material of the patterning area; and
etching the silicon base material of the patterning area.

12. A method for manufacturing a droplet discharging apparatus, comprising: a method for manufacturing a droplet discharging head including a method for manufacturing a silicon substrate including:
forming a first silicon oxide film on a surface of a silicon base material;
forming a silicon nitride film on the first silicon oxide film corresponding to a patterning area on the surface of the silicon base material;
forming a second silicon oxide film on the first silicon oxide film excluding the silicon nitride film after forming the silicon nitride film;
removing the silicon nitride film;
exposing the silicon base material of the patterning area; and
etching the silicon base material of the patterning area.
